(19) United States
(12) Patent Application Publication
(10) Pub. No.: US 2023/0154371 A1
(43) Pub. Date: May 18, 2023

(54) SUBPIXEL-BASED LIGHT FIELD DISPLAY WITH ALTERNATIVE COLOR GENERATION

(71) Applicant: IP Rodeo, LLC, Forth Worth, TX (US)

(72) Inventor: Paul Henry DIETZ, Redmond, WA (US)

(21) Appl. No.: 18/055,776

(22) Filed: Nov. 15, 2022

Related U.S. Application Data
(60) Provisional application No. 63/279,770, filed on Nov. 16, 2021.
(60) Provisional application No. 63/289,099, filed on Dec. 13, 2021.

(51) Int. Cl. G09G 3/20; G09G 3/00

(52) U.S. Cl. CPC G09G 3/2003; G09G 3/002; G09G 2300/0404

(57) ABSTRACT

A light field display includes one or more light field pixels. Each light field pixel includes differently colored light field subpixels that each project a pattern of light of a uniform (single) color. The differently colored light field subpixels are arranged close together such that a viewer perceives adjacent ones of the light field subpixels of different colors as blending together. The light field display may be formed of a lens array including lenslets, a monochrome LCD panel, and a color zoned backlight having differently colored zones respectively corresponding to the locations of the lenslets. The differently colored zones of the color zoned backlight respectively illuminate the differently colored light field subpixels.

### TECHNICAL FIELD

This disclosure relates to displays, and more particularly to subpixel-based light field displays.

### DESCRIPTION OF THE RELATED ART

Standard displays consist of many individual pixels arranged on a surface. Each pixel acts much like a small light bulb emitting a specific color and brightness of light. Typically, displays are designed so that the light from each pixel radiates uniformly over the viewing area. In this way, the image on the display when viewed from one position looks substantially the same when viewed from a different position.

This is distinctly different from what one sees when viewing a real 3-dimensional scene through a window. One could imagine the window as consisting of a matrix of very small windows, analogous to pixels, through which an observer sees a single point in each tiny window. But unlike a 2D display, what is seen through each tiny window depends not only on the scene behind the window, but also on the angle at which one looks through each pixel equivalent.

A light field display is like that window. Whereas a conventional pixel has a single brightness/color, a light field pixel can have different brightness/color for every viewing angle. A light field display reproduces the rays that would be passing through each tiny window. Light field displays are highly desirable because they can reproduce the light field generated by a real 3D scene, giving an observer the illusion of a 3D display that changes based upon viewing angle.

Light field displays are sometimes referred to as 4 dimensional displays because color/brightness must be specified at every angle (phi, theta) from each location (x, y).

Light field displays are typically constructed from conventional 2D displays through the use of a lens array and a diffuser as shown in FIG. 1. Specifically, the conventional 2D display includes a lens array, a diffuser, a color LCD (Liquid Crystal Display) panel, and a backlight, as illustrated. Each lenslet (a single lens in the lens array) covers some number of display pixels, effectively projecting those pixels out the display at different angles. In this way, each lenslet and its underlying pixels form a single light field pixel.

Color 2D displays often employ spatially distinct subpixels (e.g. Red, Green and Blue) in each pixel in order to create the illusion of continuous color. Such displays count on the limited resolution of the eye to form a spatial low pass filter that blurs the subpixels into a single, colored pixel. Virtually all current LCD and OLED (Organic Light Emitting Diode) color displays employ subpixels. FIG. 2 illustrates a sample arrangement of RGB subpixels covered by one lenslet (a single lens in the lens array) to form a single light field pixel. Unfortunately, when used with a lens array to form a light field display, these subpixels project at different angles such that an observer might only see a single subpixel from a given angle, leaving no possibility for color mixing from adjacent subpixels. To rectify this problem, diffusers (shown in FIG. 1) are frequently employed to spatially mix the colors before they are projected out. To achieve good color mixing, the material must diffuse over a significant spatial extent (at least over a full pixel width, but typically much more). This dramatically reduces the angular resolution of the light field display. What is needed is a technique that maintains the angular resolution of the light field display while achieving good color mixing.

### BRIEF SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

A light field display is provided which includes one or more light field pixels, such as a single light field pixel or a collection of light field pixels. Each light field pixel includes differently colored light field subpixels that each project a pattern of light of a uniform (single) color. The differently colored light field subpixels are arranged close together such that a viewer perceives adjacent ones of the light field subpixels of different colors as blending together. In exemplary implementations, the light field display may be formed of a lens array including lenslets (lenses), a monochrome LCD panel, and a color zoned backlight having differently colored zones respectively corresponding to the locations of the lenslets. The differently colored zones of the color zoned backlight respectively illuminate the differently colored light field subpixels.

With such configuration, the light field display has a high angular resolution because each light field subpixel projects individually controllable light beams at different angles. Further, the differently colored light field subpixels are arranged sufficiently close together to achieve good color mixing.

According to a further aspect, a method is provided for creating a light field display. The method includes preparing light field subpixels that each projects a pattern of light of a uniform (single) color; and arranging the light field subpixels close together such that adjacent ones of the light field subpixels of different colors provide an appearance of a blended color.

### BRIEF DESCRIPTION OF THE SEVERAL VIEWS OF THE DRAWINGS

FIG. 1 is a schematic diagram illustrating an example of a light field display according to the prior art;

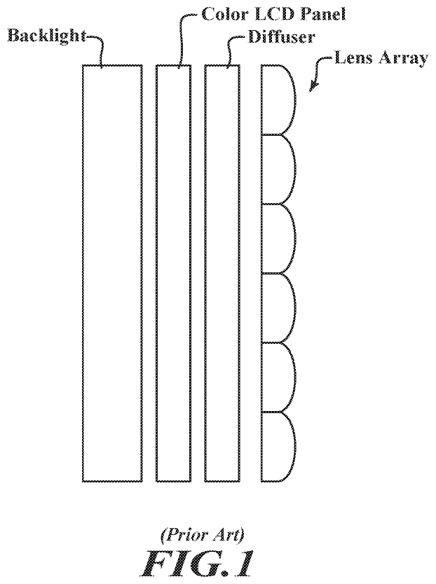

FIG. 2 is a sample arrangement of RGB subpixels covered by one lenslet to form a single light field pixel according to the prior art;

FIG. 3A illustrates a light field pixel formed of three light field subpixels, red, green and blue, each formed of a lenslet covering subpixels of a single color (red, green or blue), according to exemplary embodiments;

FIG. 3B is a side schematic view of a light field pixel formed of three light field subpixels, red, green and blue, each formed of a lenslet covering subpixels of a single color (red, green or blue), similar to the light field pixel of FIG. 3A;

FIG. 4A is a sideview of a subpixel light field display including a lens array, a monochrome LCD panel and a color zoned backlight, according to exemplary implementations;

FIG. 4B is a side schematic view of a subpixel light field display including a lens array, a monochrome LCD panel and a color zoned backlight, similar to the subpixel light field display of FIG. 4A;

FIG. 4C is a schematic view illustrating a stack of edge-lit waveguides, which is suitable for forming the color zoned backlight as included in the subpixel light field displays of FIGS. 4A and 4B;

FIG. 5A is a sideview of a subpixel light field display including a lens array and a color zoned OLED panel, according to exemplary implementations;

FIG. 5B is a side schematic view of a subpixel light field display including a lens array and a color zoned OLED panel, similar to the subpixel light field display of FIG. 5A;

FIG. 6 shows a possible arrangement of hexagonal colored regions of light field subpixels according to one embodiment;

FIG. 7 shows a possible arrangement of square colored regions of light field subpixels according to one embodiment; and

FIG. 8 shows a further possible arrangement of square colored regions of light field subpixels according to one embodiment.

### DETAILED DESCRIPTION

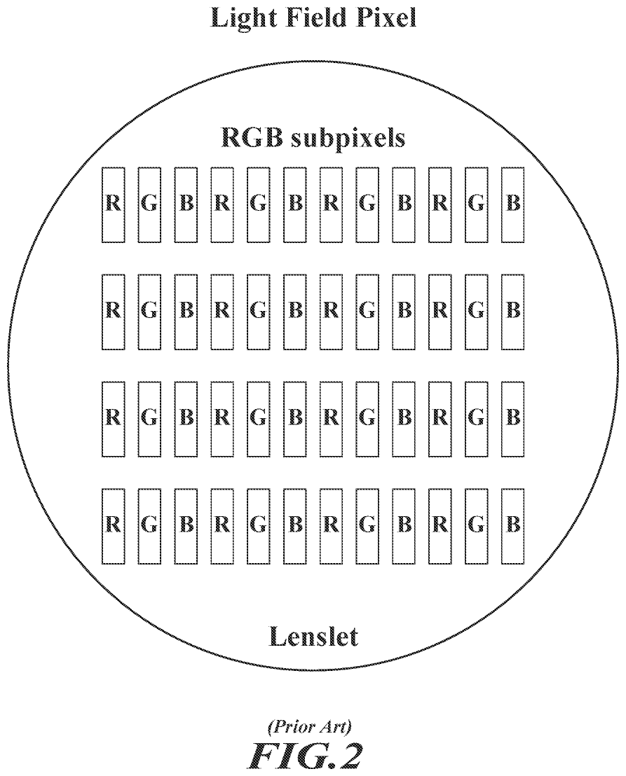

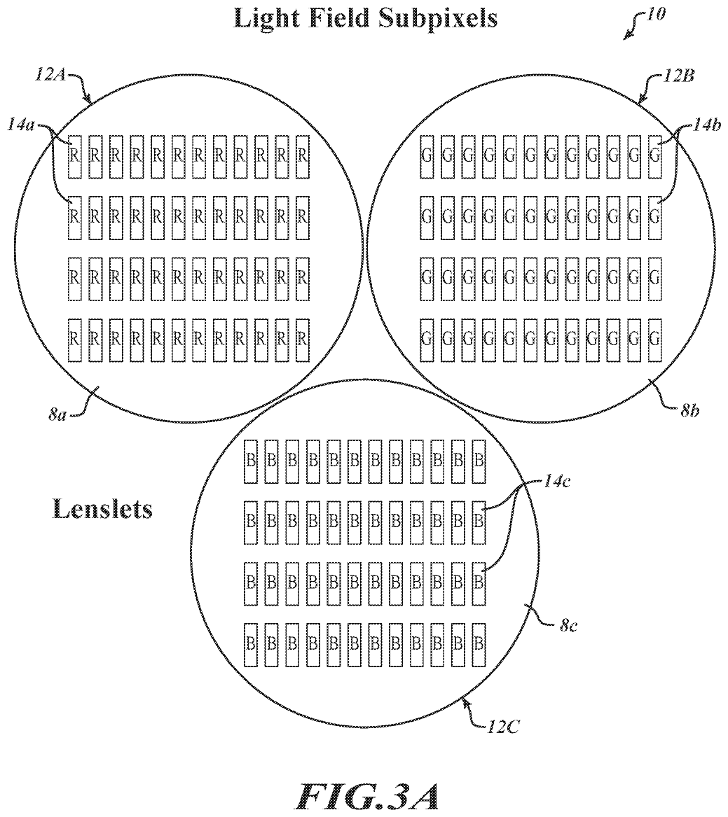

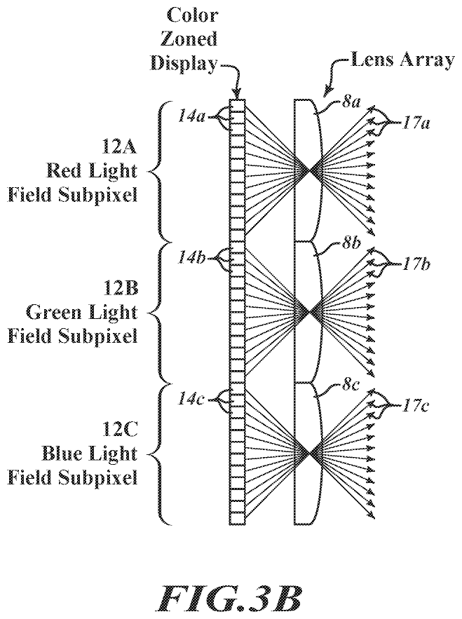

The present invention is directed to a subpixel light field display, which is formed of one or more light field pixels (e.g., one light field pixel, an array or light field pixels, or an irregularly arranged set of light field pixels), wherein each of the light field pixels is in turn formed of differently colored light field subpixels. In various implementations, each light field subpixel emits a series of individually controllable light beams at different angles and different brightness levels, but of a single apparent color per lenslet, as shown in FIGS. 3A and 3B (for example, red (R), green (G), or blue (B)). The configuration of FIG. 3A according to an embodiment of the invention, in which a lenslet covers subpixels of one color, is starkly different from the configuration of the prior art as shown in FIG. 2, in which a lenslet covers subpixels of multiple colors.

A pixel is made from a collection of subpixels that are spatially adjacent. To an observer, the subpixels in a pixel are close enough together that the emitted light appears to blend together to form a single color that is the sum of the subpixel beams visible from that observer's location.

FIG. 3A shows an exemplary embodiment of the present invention. As in conventional light field displays, there is an array of lenslets 8a, 8b and 8c that project underlying panel pixels 14a, 14b and 14c at different angles, as additionally shown in FIG. 3B. Unlike the conventional light field displays, the panel pixels 14a, 14b and 14c under each lenslet 8a, 8b or 8c do not contain differently colored panel pixels per lenslet. Instead, the panel pixels under a given lenslet according to the present invention are all of the same color to thereby constitute a light field subpixel 12. For example, a red light field subpixel 12A is formed of the lenslet 8a and the underlying red (R) panel pixels 14a. A green light field subpixel 12B is formed of the lenslet 8b and the underlying green (G) panel pixels 14b. A blue light field subpixel 12C is formed of the lenslet 8c and the underlying blue (B) panel pixels 14c. In the illustrated example of FIG. 3A, the three light field subpixels 12A (R), 12B (G) and 12C (B) in turn form a light field pixel 10.

Below are definitions of some terms used herein.

Pixel—a single picture element of a display that emits light of a controllable brightness and possibly color.

Light field subpixel 12 (e.g., 12A, 12B, 12C)—a display element of a light field display which can only emit a single color of light, but can control the intensity of the light emitted in different directions independently. Light field subpixels 12 of different colors are grouped together to form a color light field pixel 10. The light field pixel 10 is meant to be viewed from sufficiently far away such that the light field subpixel 12 colors (e.g., red, green and blue) blend together to create a range of colors for that light field pixel 10.

Light field pixel 10—a single picture element of a light field display that emits light of a controllable brightness and possibly color in many independent directions.

Panel pixel—a pixel on/of a display that emits light that is passed through a lens (lenslet) to create a beam in a given direction. Each panel pixel has a controllable brightness. The term is used to distinctly refer to the underlying display pixels as opposed to the light field pixels 10.

Lenslet—a single unit of a lens array.

FIG. 3B is a side schematic view of a light field pixel formed of three light field subpixels 12A, 12B and 12C, similar to the light field pixel 10 of FIG. 3A. In FIG. 3B, the red light field subpixel 12A is formed of a lenslet 8a covering red panel pixels 14a of a Color Zoned Display. The green light field subpixel 12B is formed of a lenslet 8b covering green panel pixels 14b of the Color Zoned Display. The blue light field subpixel 12C is formed of a lenslet 8c covering blue panel pixels 14c of the Color Zoned Display. In various implementations, each of the differently colored light field subpixels 12A, 12B and 12C projects a pattern of light of a uniform (single) color, wherein the pattern of light includes individually controllable light beams 17 of the uniform color at different angles and different brightness levels. The light beams 17 are shown schematically as a single line indicating the general direction of the light beam. In reality, as would be apparent to those skilled in the art, light from each of the underlying single-colored panel pixels 14 illuminates the underside of the lenslet to collectively create a set of beams in the direction of the arrow rather than a single beam.

In some implementations, adjacent lenslets 8a-8c may cover subpixels of a uniform color. For example, two light field subpixels 12 of the same color may be arranged to be adjacent to each other. Alternatively or additionally, the color of subpixels underlying each lenslet can be different from one lenslet to the next, as shown in FIGS. 3A and 3B. In exemplary implementations, these light field subpixels 12 may be arranged into the light field pixels 10 each containing one red light field subpixel 12A, one green light field subpixel 12B, and one blue light field subpixel 12C, as in FIGS. 3A and 3B. Other arrangements are possible. For example, red, green, blue, yellow and/or white subpixels may be used to form the light field subpixels 12 each having just one of these different colors. The differently colored light field subpixels 12 may be arranged, patterned, and grouped into one or more light field pixels 10 in various ways depending on each application as would be apparent to those skilled in the art. In various exemplary implementations, the light field subpixels 12 are sufficiently adjacent so that, when viewed from a distance, the limited resolution of the eye causes the colors of the individual light field subpixels 12 to blend together.

An advantage of the technique according to the present invention is that a diffuser is not required to blend the colors of the underlying 2D displays subpixels. Reducing or removing the diffuser can dramatically increase the angular resolution and brightness of the light field display. According to various implementations of the present invention, the color mixing occurs spatially, similar to conventional 2D displays with subpixels.

Accordingly, using the one or more light field pixels 10 each formed of differently colored light field subpixels 12 as described above, it is possible to form a subpixel-based light field display with increased angular resolution as well as increased brightness. Each of the light field subpixels 12 emits a series of individually controllable light beams at different angles and different brightness levels, but of a single apparent color. For example, as shown in FIG. 3B, the red light field subpixel 12A emits a series of individually controllable red light beams 17a from the red panel pixels 14a at different angles and different brightness levels, the green light field subpixel 12B emits a series of individually controllable green light beams 17b from the green panel pixels 14b at different angles and different brightness levels, and the blue light field subpixel 12C emits a series of individually controllable blue light beams 17c from the blue panel pixels 14c at different angles and different brightness levels. The light field pixel 10 is made from a collection of the light field subpixels 12 that are spatially adjacent. To an observer, the differently colored light field subpixels 12 in the light field pixel 10 are close enough together such that the emitted light appears to blend together to form a single color that is the sum of the light field subpixel beams (e.g., 17a, 17b and 17c) visible from that observer's location.

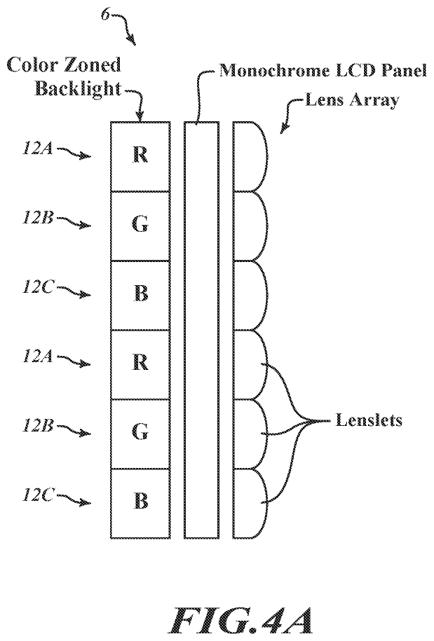

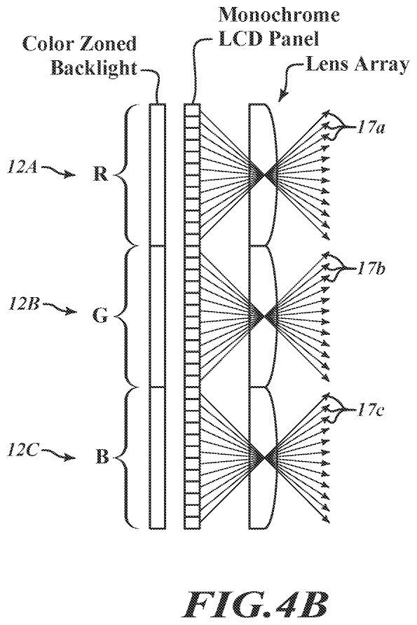

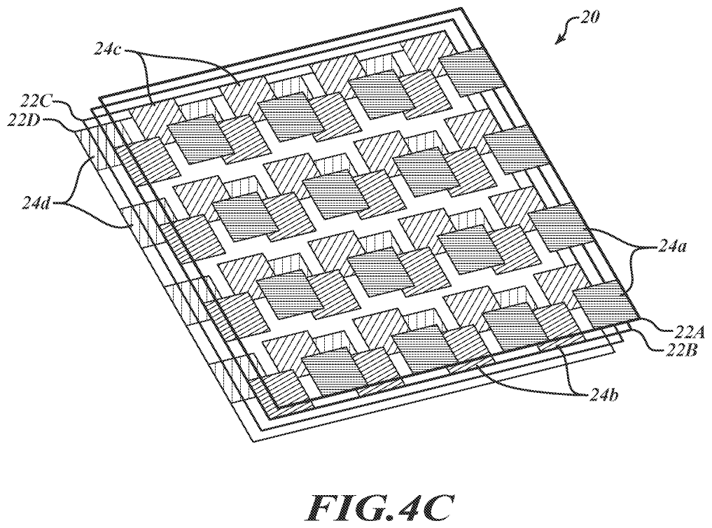

FIG. 4A shows a sideview of an embodiment of a subpixel light field display 6 formed by arranging a Lens Array and a Monochrome LCD Panel along with a Color Zoned Backlight. The Lens Array includes a plurality of lenslets. The individual color zones of the Color Zoned Backlight are arranged to correspond with the locations of the lenslets, to thereby respectively form differently colored light field subpixels 12A-12C (a total of six light field subpixels 12A-12C are illustrated). The color zones of the Color Zoned Backlight may be created using various technologies, such as different colored LEDs (light emitting diodes). In this way, each lenslet projects only one color (R, G or B), for example based on RGB LEDs which form the Color Zoned Backlight, and therefore there is no need for a color mixing stage. Thus, a diffuser may be omitted. A minimal diffuser may be added to help bridge the gap between the monochrome pixels, though this will have little impact on the high angular resolution of the display 6.

FIG. 4B is a side schematic view of a subpixel light field display including a Lens Array, a Monochrome LCD Panel, and a Color Zoned Backlight, similar to the subpixel light field display of FIG. 4A, except that only three light field subpixels 12A-12C are illustrated in FIG. 4B. As illustrated, three different color zones (R, G, B) of the Color Zoned Backlight respectively illuminate three sets of pixels of the Monochrome LCD Panel to thereby form the different colored light field subpixels 12A (R), 12B (G), and 12C (B). The configuration of the subpixel light field display as illustrated does not require use of a color mixing diffuser or LCD color filters, thereby improving angular resolution/pixel density as well as display brightness. Each of the differently colored light field subpixels 12A (R), 12B (G), and 12C (B) projects a pattern of light of a uniform (single) color, wherein the pattern of light includes individually controllable light beams of the uniform color at different angles and different brightness levels. As illustrated, each of the monochrome LCD panel pixel forms an independent beam 17 (17a, 17b, or 17c) of a single color.

Another advantage of the present invention is that it is far more optically efficient as compared with conventional light field displays. The color filters on a conventional color LCD panel inherently throw away ⅔ of the light from a white backlight. In the present invention, the colors of the backlight can be created very efficiently using different colored LEDs (light emitting diodes) or laser light sources. Due to this optical efficiency and the removal of the diffuser, the present invention is capable of producing a much brighter display than a conventional light field display using the same amount of power.

There are numerous ways of producing a Color Zoned Backlight for use in the present invention. For example, the different color zones can be created by using a single, appropriately colored LED in each zone. For dense displays, micro-LED techniques can be employed. Alternatively, a conventional white backlight could be used by inserting an appropriately constructed color filter. It is to be noted that color filters can alternatively be placed in the LCD panel, between the LCD panel and the lenslet, or even external to the lenslet to achieve the same effect. In these embodiments, filtering may lose the efficiency gains of removing the LCD color filter. To some degree, some of such light could be recovered by constructing the filter using materials such as dichroic filters that pass one color of light while reflecting others. Light recycling techniques are frequently employed in conventional LCD displays, and these techniques can be well utilized for the present invention.

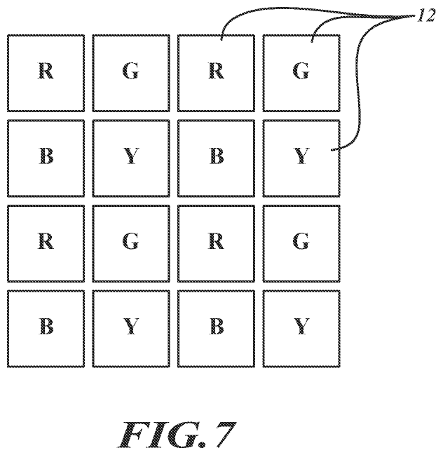

Conventional backlights often use an edge-lit waveguide to spread the light evenly. Waveguides can also be used to construct the Color Zoned Backlight according to various implementations. An embodiment of the present invention may use a stack of edge-lit waveguides, one for each color, to bring light to the appropriate regions, as shown in FIG. 4C. FIG. 4C is a schematic view illustrating a stack 20 of edge-lit waveguides 22A, 22B, 22C and 22D, suitable for forming a Color Zoned Backlight as included in the subpixel light field displays of FIGS. 4A and 4B, described above. The illustrated example of the stack 20 includes four layers of edge-lit waveguides, though more or less than four layers of edge-lit waveguides may be used depending on a particular application. In the illustrated example, the four layers of the edge-lit waveguides 22A-22D are each formed of a transparent material to bright light to differently colored regions 24a-24d. For example, the edge-lit waveguides 22A-22D may respectively include blue regions 24a, yellow regions 24b, green regions 24c, and red regions 24d. Thus, when assembled together, the stack 20 provides a pattern of four colored zones, somewhat similar to a pattern as shown in FIG. 7. The stack 20 works because the regions that are not emitting light can be transparent (passing their light via total internal reflection), allowing light rays mostly normal to the surface to pass through from the other waveguides. This technique allows for dense color zone spacing using a relatively small number of LEDs for edge lighting. This may be particularly useful for near-to-eye displays.

Lens arrays often exhibit wavelength dependency. The stacked waveguide design allows the different light emitting locations along the waveguides to be at different focal points, appropriate for their individual wavelengths. This will typically result in the waveguides being stacked in the order of their wavelengths.

In other embodiments of the present invention, quantum dots or phosphors are utilized to create the different color zones of a Color Zoned Backlight. For example, a conventional edge-lit backlight can be illuminated with blue LEDs, with red and green areas created by patterning quantum dots in the appropriate areas. In this case, the blue light is provided directly to the blue areas, while the red and green areas are illuminated by the excited quantum dots in those areas. Similarly, phosphors could be employed to create the different colors when suitably excited, for example, by an ultraviolet backlight. Quantum dots or phosphors can be utilized between the backlight and the LCD panel, inside the LCD panel (but not between the polarizers because polarization is not maintained), or between the LCD panel and the lenslet. Because the quantum dots and phosphors generally do not preserve the direction of the exciting light, but rather emit light over a wide angular range, it may be difficult to use the quantum dots and phosphors on the outside of the lenslet.

Quantum dots and phosphors scatter emitted light in many directions. To prevent backpropagation of colored light into the backlight waveguide, a simple filter can be used which preferentially passes the backlight wavelength and blocks the other wavelengths. A dichroic filter tuned to the backlight wavelength can further improve performance by reflecting the generated colors back in the direction of the quantum dot or phosphor, recycling these scattered rays while also preventing undesirable back propagation through the waveguide.

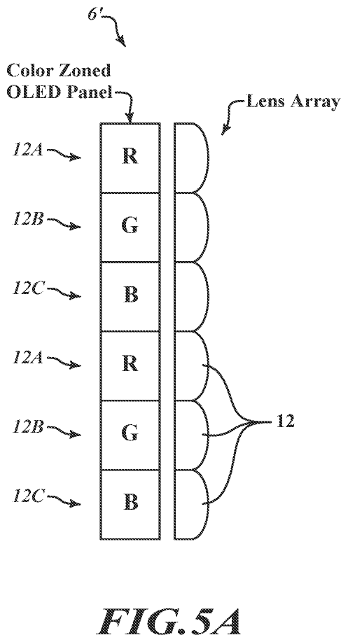

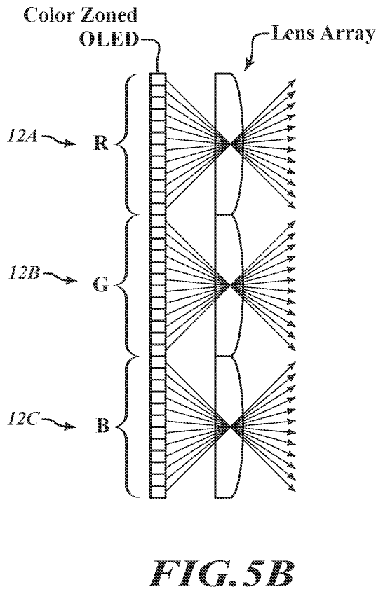

In another alternative embodiment, a color zoned emissive display panel, such as a specialized OLED panel, is employed to form a subpixel light field display 6′ as shown in FIG. 5A. In this case, the OLED panel has areas of singularly colored pixels (R, G or B) corresponding to the locations of the lenslets, to thereby form light field subpixels 12A-12C each of a single color (a total of six light field subpixels 12A-12C are illustrated).

FIG. 5B is a side schematic view of a subpixel light field display including a Lens Array and a Color Zoned OLED panel, similar to the subpixel light field display of FIG. 5A, except that only three light field subpixels 12A-12C are illustrated in FIG. 5B. As illustrated, three sets of pixels of the Color Zoned OLED panel of three different colors, R, G and B, respectively, illuminate three lenslets of the Lens Array to thereby form the differently colored light field subpixels 12A (R), 12B (G), and 12C (B). Each of the differently colored light field subpixels 12A (R), 12B (G), and 12C (B) projects a pattern of light of a uniform (single) color, wherein the pattern of light includes individually controllable light beams of the uniform color at different angles and different brightness levels. In other implementations, in place of the Color Zoned OLED panel as shown in FIGS. 5A and 5B, a color zoned micro LED panel or a color zoned plasma display panel may be used to form the color zoned emissive display panel, to emit different sets of single-color (uniform-color) light beams (e.g., R, G, or B) through different lenslets of the Lens Array, respectively.

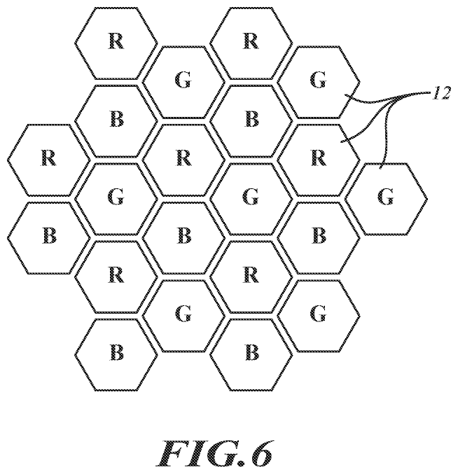

FIG. 6 shows a possible arrangement of hexagonal colored regions of light field subpixels 12. Many other arrangements are possible.

FIG. 7 shows an alternative arrangement of square colored regions of light field subpixels 12, using red, green, blue and yellow light field subpixels 12 in a square arrangement.

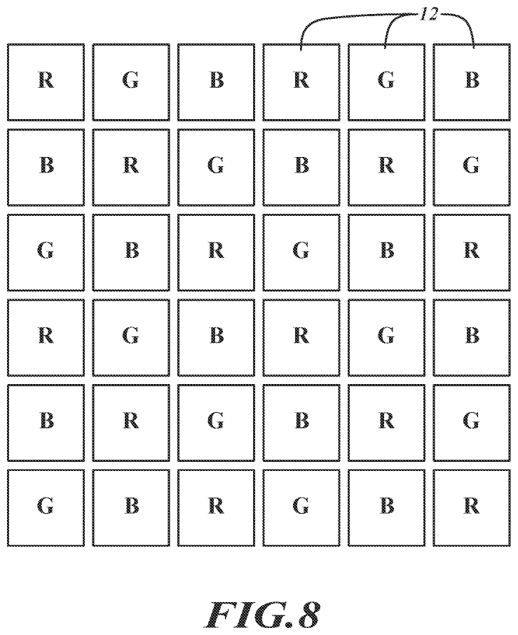

FIG. 8 is yet another alternative arrangement of square colored regions of light field subpixels 12, using red, green and blue light field subpixels 12.

The arrangements shown in FIGS. 6-8 are provided as non-limiting examples only, and many other arrangements are possible as would be apparent to those skilled in the art.

In some implementations, light field subpixels 12 can be designed to each emit a narrow spectral bandwidth of light. For example, if lasers are used as the light source, each light field subpixel 12 is essentially monochromatic. Typically, lens design is constrained by chromatic aberration. This is not the case for the present invention which utilizes single color light field subpixels 12. Lenslets 8 of a subpixel light field display 6 can be designed or optimized separately for each light field subpixel color to project each color over a similar angular extent as the other colors. Thus, sharper displays with simple lenslets become possible. If the light field subpixels 12 are each essentially monochromatic, the lenslets 8 for different color light field subpixels can be realized using diffractive optics.

Another way of making subpixel light field displays 6 is by using an array of individual projectors with each projector forming a light field pixel 10. To get color mixing, such displays can utilize projectors that use field sequential color rather than projectors that display spatially distinct subpixels. Unfortunately, field sequential color systems suffer from artifacts such as the individual colors tearing apart when the eye moves relative to the display. In another embodiment of the invention, monochrome projectors of different colors are used to form light field subpixels 12 of different colors. These monochrome projectors can be simpler and thus less expensive. This technique eliminates the disturbing color tearing artifacts associated with field sequential color systems.

Because the present invention is a type of subpixel display, well known subpixel rendering techniques can be employed. For example, a standard technique for improving the apparent resolution of fonts is to regroup the subpixels, using the subpixels in different pixels to form slightly shifted pixel locations.

In some embodiments of the present invention, it is relatively straightforward to include additional LEDs to be able to change the color of a subpixel from moment to moment. For example, the R-G-B subpixels could be cycling on each frame, going from RGB to GBR to BRG. Such cycling could aid in the perceptual color mixing, particularly in the case when the subpixels spacings are almost resolvable by the human eye. Note that this is quite distinct from field sequential color because the correct spatial color mixing is available at every moment.

Light field displays 6 have a number of important use cases. The dominant application is to provide a highly realistic view of a 3D scene. In head mounted displays, light field displays can address the accommodation/vergence conflict that arise from the use of conventional displays. Multiview displays are light field displays that are used to simultaneously show different content to multiple viewers based on their positions relative to the display. Light field displays have also been used to light a scene, simulating complex lighting arrangements such as multiple spotlights with different beam patterns shining from different locations. In some cases, light field displays may be non-planar, with irregular spacing, for example, when used to provide occlusion effects in drone light shows. The present invention is applicable to all these use cases, as well as any others where light fields are utilized.

While preferred implementations of the present disclosure have been illustrated and described, numerous variations of the illustrated and described arrangements of features will be apparent to one skilled in the art based on the disclosure. Various alternative forms may be used to implement the principles disclosed herein. In addition, the various implementations described above can be combined to provide further implementations.

What is claimed is:

1. A light field display comprising:
one or more light field pixels, wherein each light field pixel includes differently colored light field subpixels that each project a pattern of light of a uniform color and that are arranged close together such that a viewer perceives adjacent ones of the light field subpixels of different colors as blending together,
wherein the pattern of light projected by each of the light field subpixels includes individually controllable light beams at different angles.

2. The light field display of claim 1, wherein the pattern of light projected by each of the light field subpixels includes individually controllable light beams at different angles and different brightness levels.

3. The light field display of claim 1, comprising:
a lens array including lenslets;
a monochrome LCD (liquid crystal display) panel; and
a color zoned backlight having differently colored zones respectively corresponding to the locations of the lenslets,
wherein the differently colored zones of the color zoned backlight respectively illuminate the differently colored light field subpixels.

4. The light field display of claim 3, wherein the color zoned backlight comprises:
an array of light emitting diodes of different colors, wherein the light emitting diode(s) of one color are arranged to light a region of the monochrome LCD panel corresponding to one of the lenslets.

5. The light field display of claim 3, wherein the color zoned backlight comprises:
a stack of edge-lit waveguides, wherein each edge-lit waveguide provides a different color of illumination to distinct regions of the monochrome LCD panel corresponding to the locations of the lenslets.

6. The light field display of claim 3, wherein the color zoned backlight comprises:
a backlight that is patterned with quantum dots or phosphors so as to provide defined color light to distinct regions of the monochrome LCD panel corresponding to the locations of the lenslets.

7. The light field display of claim 1, comprising:
a lens array including lenslets; and
a color zoned emissive display panel including differently colored zones respectively corresponding to the locations of the lenslets,
wherein the differently colored zones of the color zoned emissive display panel respectively illuminate the differently colored light field subpixels.

8. The light filed display of claim 7, wherein the color zoned emissive display panel is a color zoned OLED (organic light emitting diode) panel, a color zoned micro LED (light emitting diode) panel, or a color zoned plasma display panel.

9. The light field display of claim 1, comprising:
an array of projectors each forming one light field pixel.

10. The light field display of claim 1, wherein the differently colored light field subpixels have hexagonal shapes.

11. The light field display of claim 1, wherein the differently colored light field subpixels have square shapes.

12. The light field display of claim 1, wherein the differently colored light field subpixels include red, green, and blue light field subpixels.

13. The light field display of claim 12, wherein the differently colored light field subpixels include red, green, blue, and yellow light field subpixels.

14. The light field display of claim 1, which does not include a diffuser.

15. A method of creating a light field display, comprising:
preparing light field subpixels that each projects a pattern of light of a uniform color; and
arranging the light field subpixels close together such that adjacent ones of the light field subpixels of different colors provide an appearance of a blended color.

16. The method of claim 15, wherein the pattern of light projected by each of the light field subpixels includes individually controllable light beams at different angles.

17. The method of claim 15, wherein optical elements of the light field subpixels are designed for defined wavelength ranges of the light field subpixels, respectively, such that projections from the different color light field subpixels project over corresponding angles.

18. The method of claim 15, comprising:
layering a lens array including lenslets, a monochrome LCD (liquid crystal display) panel, and a color zoned backlight having differently colored zones respectively corresponding to the locations of the lenslets, to prepare the light field subpixels configured to be respectively illuminated by the differently colored zones of the color zoned backlight.

19. The method of claim 18, comprising:
using an array of light emitting diodes of different colors to form the color zoned backlight.

20. The method of claim 16, comprising:
layering a lens array including lenslets and a color zoned OLED (organic light emitting diode) panel including differently colored zones respectively corresponding to the locations of the lenslets, to prepare the light field subpixels configured to be respectively illuminated by the differently colored zones of the color zoned OLED panel.
